(19) United States
(12) Patent Application Publication
(10) Pub. No.: US 2006/0027924 A1
(43) Pub. Date: Feb. 9, 2006

(54) Metallization layers for crack prevention and reduced capacitance

(75) Inventors: Pi-Tsung Chen, Tainan (TW); Yung-Cheng Lu, Taipei (TW); Syun-Ming Jang, Hsin-Chu (TW)

Correspondence Address: TUNG & ASSOCIATES, 838 W. Long Lake Road, Suite 120, Bloomfield Hills, MI, 48302, US

(73) Assignee: Taiwan Semiconductor Manufacturing Co., Ltd.

(21) Appl. No.: 10/910,479

(22) Filed: Aug. 3, 2004

(51) Int. Cl. H01L 23/52

(52) U.S. Cl. 257/751

(57) ABSTRACT

A semiconductor device and method for forming the device wherein the device includes a substrate; a dielectric insulating layer formed overlying the substrate; a metal filled dual damascene structure formed in the dielectric insulating layer, wherein the metal filled dual damascene structure includes a via portion and a trench portion; and at least one intervening dielectric layer in compressive stress formed in the dielectric insulating layer and disposed at a level adjacent to at least one of the via portion and the trench portion of the metal filled dual damascene structure.

### FIELD OF THE INVENTION

This invention generally relates to multi-layered semiconductor structures and more particularly to a method for preventing stress-induced cracking in multi-level integrated circuit devices.

### BACKGROUND OF THE INVENTION

The escalating requirements for high density and performance associated with ultra large scale integration semiconductor wiring require increasingly sophisticated interconnection technology. As device sizes decrease it has been increasingly difficult to provide interconnection technology that satisfies the requirements of low RC (resistance capacitance) metal interconnect properties, particularly where sub-quarter micron characteristic dimension integrated circuit wiring is formed in multiple stacked levels (dielectric layers).

In the fabrication of semiconductor devices, increased device density requires multiple levels of wiring, making necessary the provision of a multi-layered metal interconnect structures. Such a multi-layered interconnect structure typically includes inter-layer metal interconnects (wiring), also referred to as vias and intra-layer metal interconnects, also referred to as trench lines. The intra-layer metal interconnects including trench lines are also referred to as metallization layers, typically including metal damascene structures formed in one or more dielectric insulating layers. In one manufacturing approach, trench lines are formed overlying and encompassing vias to form dual damascene interconnect structures where both the via and trench line openings are simultaneously filled with metal.

In a typical process for forming multiple layer interconnect structure, for example, a dual damascene process, a dielectric insulating layer, also referred to as an inter-metal dielectric (IMD), is deposited for forming damascene metal interconnects, also referred to as a metallization layer, e.g., M1, M2, M3, etc., depending on the number of preceding metallization layers. In one approach to forming a dual damascene structure a high aspect ratio opening referred to as a via is then etched through the dielectric insulating layer by conventional photolithographic and etching techniques. Another etched opening referred to as a trench line is then formed overlying and encompassing one or more via openings. The via opening and the trench line together makeup the dual damascene structure which is subsequently filled with metal, for example, copper, followed by a planarization process such as a chemical mechanical polish (CMP) to prepare the process surface for formation of another overlying metallization layer in a multi-level semiconductor device.

Signal transport speed is of great concern in the semiconductor processing art for a number of reasons. The signal transport speed of semiconductor circuitry, also referred to as the RC time constant, varies inversely with the resistance and capacitance (RC) of the interconnections. As integrated circuits become more complex and feature sizes decrease, the effect of the RC time constant on signal delay becomes critical. The formation of multi-level integrated circuit devices increasingly requires novel manufacturing approaches to reduce the capacitance of the dielectric layers while maintaining device robustness to withstand processing and operating induced thermal stresses.

For example, one way to reduce capacitance is to reduce the capacitance of the dielectric insulating layers making up the multi-layered IC device. Several approaches have been proposed including the use of low dielectric constant (low-K) materials for forming the metallization and IMD layers. For example, the use of silicon dioxide based porous materials has been one low-K material that has been used with some success. The use of porous low-K materials has a major drawback, however, in that they typically have lowered strength and are more susceptible to stress-induced cracking. For example, in a multi-level IC device manufacturing process each layer is subjected to thermal stresses during and following the manufacturing process. The magnitude of the stresses, for example tensile stresses, produced in each level of the IC device produce a cumulative effect of increasing stress with the formation of each successive overlying level of the IC device. The probability of catastrophic failure (e.g., cracking) of the dielectric insulating layers increases with the formation of each successive metallization layer. The presence of cracking in the dielectric layers is frequently difficult to detect, and when detected results in scrapping of the IC device. Such stress-induced cracking is therefore a limiting factor in the integration of multi-level IC devices, reducing both yields and the reliability of the IC device.

There is therefore a need in the integrated circuit processing art to provide a multi-level metallization layer structure and method for forming the same to reduce the cumulative effect of stress buildup thereby reducing the incidence of cracking failure in multi-level integrated circuit devices to improve both yield and reliability.

It is therefore among the objects of the present invention to provide a multi-level metallization layer structure and method for forming the same to reduce the cumulative effect of stress buildup thereby reducing the incidence of cracking failure in multi-level integrated circuit devices to improve both yield and reliability, in addition to overcoming other shortcomings and deficiencies in the prior art.

### SUMMARY OF THE INVENTION

To achieve the foregoing and other objects, and in accordance with the purposes of the present invention, as embodied and broadly described herein, the present invention provides a stacked metallization layer integrated circuit structure and method for forming the same for reducing a tensile stress thereby improving a resistance to cracking.

In a first embodiment, the method includes providing a semiconductor process wafer; forming a dielectric insulating layer over the semiconductor process wafer comprising at least one intervening dielectric layer formed in compressive stress at a level adjacent to at least one of a via portion and a trench portion comprising a subsequently formed metal filled dual damascene; and, forming the metal filled damascene.

These and other embodiments, aspects and features of the invention will become better understood from a detailed description of the preferred embodiments of the invention which are described in conjunction with the accompanying drawings.

### BRIEF DESCRIPTION OF THE DRAWINGS

FIGS. 1A-1D are representational cross sectional side views of a portion of a stacked metallization integrated circuit structures formed according to embodiments of the present invention.

FIG. 2 is a modeled data representation of capacitance values versus vertical position (height) with respect to an exemplary metallization layer including a dual damascene structure used to determine a desired level to form compressive stress dielectric layers according to an embodiment of the present invention.

FIG. 3 is a process flow diagram including several embodiments of the present invention.

### DETAILED DESCRIPTION OF THE PREFERRED EMBODIMENTS

Although the method of the present invention is explained by exemplary reference the formation of a dual damascene structure according to a via-first method of formation in a multi-level semiconductor device it will be appreciated that the method of the present invention is equally applicable to other methods of dual or single damascene structure formation including for example stacked vias and damascene structures such as bonding pads. While the method of the present invention is particularly advantageously implemented with respect to copper filled dual damascene structures, it will be appreciated that the method may be adapted for use with other metal fillings, for example including tungsten, aluminum, and copper and alloys thereof. Further, the term ‘copper’ will be understood to include copper and alloys thereof.

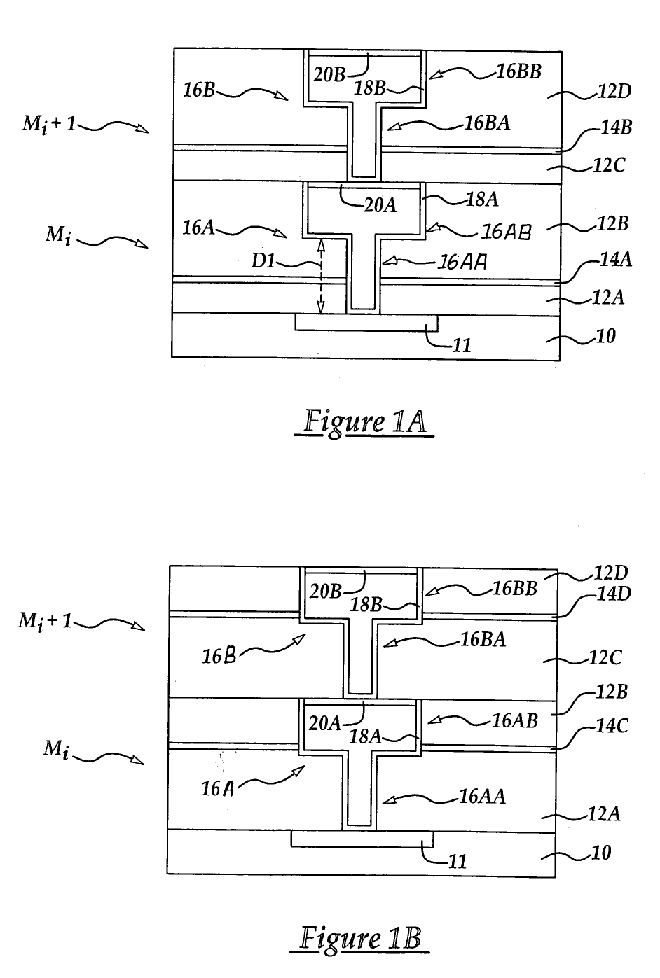

For example, referring to FIG. 1A is shown a schematic representation of a cross sectional portion of a multi-level semiconductor device formed according to an embodiment of the invention. Shown are stacked dual damascene structures 16A and 16B formed in dielectric insulating layers 12A, 12B, 12C, and 12D. In an important aspect of the invention, in one embodiment, thin dielectric layer portions e.g., 14A and 14B are formed in compressive stress separating dielectric insulating layer portions 12A and 12B and 12C and 12D. In one embodiment, the thin dielectric layer portions e.g., 14A and 14B are preferably formed at a level adjacent the via portions e.g., 16AA and 16BA corresponding to about a minimum in capacitance as modeled by conventional electrical capacitance metallization layer modeling methods, preferably using modeled stacked metallization layers without the thin dielectric layer portions e.g., 14A and 14B, to determine a minimum capacitance level versus height in a model metallization layer. For example, the thin dielectric layers portions e.g., 14A and 14B are preferably disposed at a level within a depth e.g., D1 corresponding to the depth of the via portion of the dual damascene e.g., 16AA determined by finding a minimum level in capacitance within the respective metallization layer, e.g., Mi and Mi+1 adjacent the respective dual damascene structure e.g., 16A and 16B. For example, the thin dielectric layers e.g., 14A and 14B are formed at a level about midway with respect to the via portion depths e.g., D1 of via portions 16AA and 16BA.

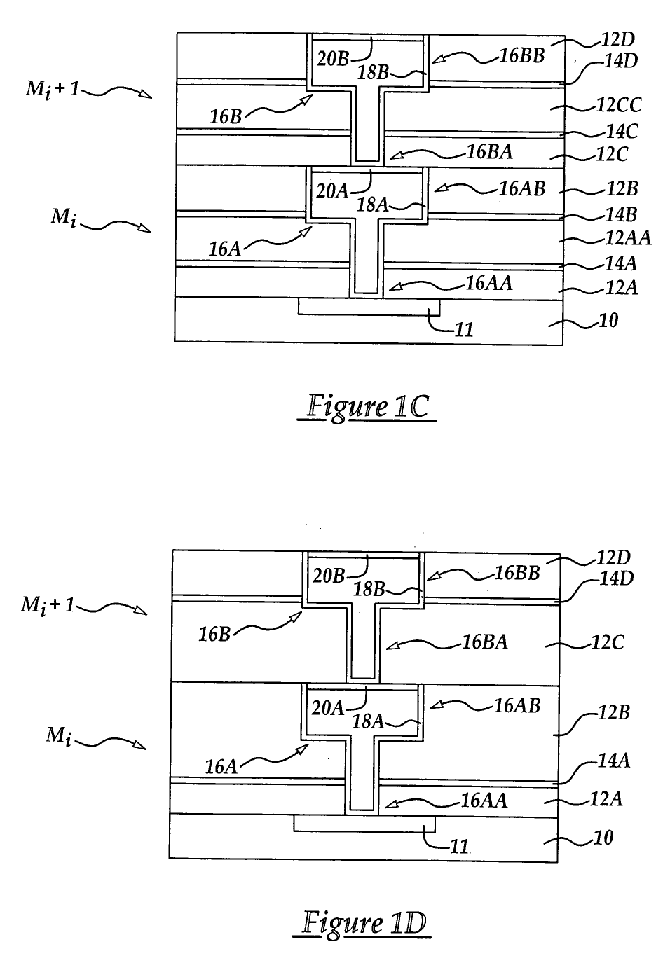

For example referring to FIG. 2 is shown a modeled normalized capacitance value of a model metallization layer on the vertical axis determined by a conventional capacitance modeling methods according to the depth (height) position (e.g., measured from the via bottom portion) of an exemplary dual damascene formed according to preferred embodiments without the compressive thin dielectric layers portions e.g., 14A and 14B inserted. Data corresponding to the via portion of the dual damascene structure is shown to the left (arrow B1) of line B and data corresponding to the trench line portion is shown to the right (arrow B2) of line. The data line A represents the normalized capacitance value of the model metallization layer versus height (measured from the via bottom portion) adjacent a model dual damascene structure. The most preferable position to insert the compressive dielectric layer portion e.g., 14A and 14B is shown at about position C, corresponding to about a minimum value in capacitance in the modeled metallization layer.

Referring back to FIG. 1A, in an exemplary implementation for forming stacked dual damascene structures, first dielectric insulating layer portion 12A is formed by conventional processes over an underlying material layer e.g., a dielectric insulating layer 10 including a conductive area 11, for example a metal (e.g., copper) interconnect. The dielectric insulating layer 10 or 12A may additionally overlie and be in electrical communication with a semiconductor substrate (not shown) including CMOS devices (not shown). The first dielectric insulating layer portion 12A is preferably formed of a low-K (low dielectric constant) material, more preferably formed of a silicon oxide based low-K material having a porous structure, for example including interconnecting pores, preferably having a dielectric constant of less than about 3.0, for example from about 2.2 to about 3.0.

The first dielectric insulating layer portion 12A, for example is formed by a PECVD process including organo-silane precursors such as methylsilanes, for example, tetramethylsilane and trimethylsilane. In addition, organo-siloxane precursors such as cyclo-tetra-siloxanes may be used to form the first dielectric insulating layer portion 12A.

Still referring to FIG. 1A, a thin dielectric layer portion 14A is deposited to form a thin film in compressive stress over the first dielectric layer portion 12A. The compressive dielectric layer 14A is preferably deposited by a CVD process, for example LPCVD, APCVD, or PECVD, more preferably LPCVD, to form a film in compressive stress relative to at least an underlying layer and preferably an overlying layer. For example, by altering the relative amounts of reactants in CVD depositions a film may be deposited with a selected stoichiometry to have a compressive stress relationship to underlying layers. Preferably the thin dielectric layer portion e.g., 14A formed in compressive stress have a compressive stress value greater than about 0.5×10⁹ dynes/cm², more preferably, greater than about 1.0×10⁹ dynes/cm². Preferably, the first dielectric insulating layer portion 12A is formed to a thickness such that the compressive dielectric layer e.g., 14A is formed at a point of about minimum capacitance in the subsequently formed via portion 16AA of the dual damascene structure 16A, for example, at about the midway level of the via portion e.g., 16AA. It will be appreciated that the thickness of the thin dielectric layer 14A will vary depending on the material and the overall acceptable contribution to capacitance of the metallization layer and the magnitude of compressive stress desired to offset the tensile stresses present in the underlying and overlying dielectric insulating layers. For example, the thin dielectric layer 14A is formed at a thickness of about 50 Angstroms to about 700 Angstroms, more preferably from about 50 to about 200 Angstroms in thickness.

The thin dielectric layer portion 14A is preferably formed of one or more layers of silicon nitride (e.g., SiN), silicon oxynitride (e.g., SiON), silicon carbide (e.g., SiC), silicon oxycarbide (e.g., SiOC or SiCO), and silicon carbide nitride (e.g., SiCN). It will be appreciated that stoichiometry of the respective dielectric layers may be varied according to known CVD processing variables, including altering relative ratios of reactants to achieve a desired compressive stress of the film.

Still referring to FIG. 1A, the dual damascene structure, e.g., 16A is preferably formed by a via-first process whereby conventional photolithographic patterning and dry etching processes, for example a reactive ion etch (RIE) process, are carried out to first etch a via opening through dielectric insulating layers 12A and 12B, followed by formation of an overlying trench portion e.g., 16AB, to form a dual damascene structure e.g., 16A. The dual damascene structure is then lined with a barrier layer e.g., 18A by a blanket deposition process, for example a PVD process. The barrier layer e.g., 18A is preferably includes at least one material layer selected from a refractory metal, refractory metal nitride, and silicided refractory metal nitride, for example Ta, Ti, W, TaN, TiN, WN, TaSiN, TiSiN, and WSiN. In a preferred embodiment, the barrier layer e.g., 18A is formed of Ta/TaN, TaN, or TaSiN, most preferably, a Ta/TaN composite layer.

Still referring to FIG. 1A, the dual damascene opening is then filled with metal, preferably copper deposited by a conventional electrochemical deposition (ECD) process following formation of a PVD copper seed layer (not shown) over the barrier layer 18A. The copper filled dual damascene structure 16A is then planarized, for example by a CMP process to the trench level, preferably removing any overlying dielectric hardmask layers (not shown) and ARC layers to reveal the first dielectric insulating layer portion 12B surface.

In a preferred embodiment of the invention, a metal capping layer e.g., 20A is preferably selectively deposited to form a protective layer over the upper portion of the copper filled dual damascene 16A. A recessed area in the upper portion of the copper filled dual damascene e.g., 16A may first be formed by CMP overpolishing or formed by chemically or thermally oxidizing upper portions of the planarized copper portion followed by wet etching away the formed copper oxide to from a recessed area having an exposed copper portion at the upper portion of the dual damascene, for example having a depth from about 100 Angstroms to about 300 Angstroms. Preferably, the metal capping layer e.g., 20A is formed over the exposed copper portion by electroless deposition of a nickel, tungsten or cobalt alloy, such as CoWP, and CoWB, more preferably COWB. For example, an electroless plating solution including a reducing agent is used to plate out metallic constituents in the plating solution selectively onto the upper exposed copper portion of the dual damascene structure e.g., 16A, to form metal capping layer 20A. The exposed copper portion may optionally include a deposited catalyzing agent such as Pd, deposited by conventional methods. Preferably, the plating solution includes a reducing agent including hypophosphite (H₂PO₂) and dimethyl amine borane (DMAB). The selectively electroless deposited metal capping layer 20A is formed at a thickness of about 100 Angstroms to about 300 Angstroms to fill the dual damascene to the trench level. An optional annealing process at about 400° C. to about 550° C. is carried out following the electroless deposition process. It will be appreciated that, less preferably, due to additional capacitance contribution, a capping layer, for example, selected from the same materials as the compressive dielectric layers (e.g., 14A and 14B) may be formed by conventional CVD blanket deposition over the planarized dual damascene structure.

Still referring to FIG. 1A, the processes outlined above to form dual damascene structure 16A are repeated to form overlying dual damascene structures e.g., 16B including the compressive dielectric layer 14B formed at about the same preferred level adjacent the via portion e.g., 16BA as determined according to preferred embodiments discussed for compressive dielectric layer 14A. The barrier layer e.g., 18B and metal capping layer 20B are also formed according to the same preferred embodiments. It will be appreciated that the dual damascene formation process according to preferred embodiments may be repeated to form multiple stacked dual damascene structures in multiple stacked metallization layers. In addition, it will be appreciated that the trench line portion e.g., 16AB, and 16BB of the dual damascene structures 16A and 16B may overlie and encompass more than one via opening.

Referring now to FIG. 1B, is shown another embodiment of a stacked metallization layers including dual damascene structures where similar numbered reference numerals refer to the same elements previously described except for the positioning of the compressive dielectric layers which now shown as 14C and 14D. The compressive dielectric layers 14C and 14D in this embodiment are preferably formed at about the level of the transition between the trench portion e.g., 16AB and the via portion e.g., 16AA. More preferably, the compressive dielectric layers 14C and 14D are formed adjacent the trench line portion, slightly above the transition between the trench portion e.g., 16AB and the via portion e.g., 16AA, for example about 50 Angstroms to about 700 Angstroms above the bottom level of the trench portion.

In this embodiment, the compressive dielectric layers 14C and 14D, formed in compressive stress relationship with respect to at least underlying and preferably overlying dielectric insulating layers advantageously additionally serves as an etch stop layer, for example where the trench portion e.g., 16AB is etched through the thickness of the compressive dielectric layers e.g., 14C and into a portion of the underlying insulating dielectric layer e.g., 12A for a predetermined distance e.g., about 50 Angstroms to about 300 Angstroms. By positioning the compressive dielectric layers e.g., 14C and 14D adjacent the trench portion e.g., 16AB and 16BB, the compressive stress of the dielectric layers better offsets (counteracts) tensile stresses present in the overlying and underlying dielectric insulating layers, e.g., 12A and 12B as well as serves as an etch stop layer for more accurately etching a trench portion depth.

Referring to FIG. 1C, in another embodiment, it will be appreciated that compressive dielectric layers e.g., 14A, 14C, 14B, 14D may be included both adjacent via portions and adjacent trench portions according to preferred embodiments shown in FIGS. 1A and 1B, requiring the formation of insulating dielectric layer portions e.g., 12AA, and 12CC.

Referring to FIG. 1D, the positioning of the compressive dielectric layers e.g., 14A, and 14D may additionally be altered in positioning in successively stacked metallization layers, for example, adjacent the via portion in metallization layer Mi according to preferred embodiments discussed in FIG. 1 for dual damascene structure 16A and adjacent the trench portion in metallization layer M i+1 for dual damascene structure 16B and so on in successive metallization layers.

It will be appreciated that the compressive dielectric layers may be formed at about the level of the transition between the trench portion, e.g., 16AB and/or 16BB of the dual damascene structures, e.g., 16A and/or 16B, in either or both the metallization levels Mi and Mi+1 and that the compressive stress dielectric layers, e.g., compressive dielectric layers 14A, 14B, 14C, and 14D in this case may serve as both hardmask layers/compressive dielectric layers in the embodiments shown in FIGS. 1A through 1D., e.g., hardmask layers in the etching of via and/or trench portions of the dual damascene structures 16A and/or 16B. It will additionally be appreciated that conventional hardmask layers at the transition between trench portion, e.g., 16AB and/or 16BB of the dual damascene structures, e.g., 16a and/or 16B may be provided.

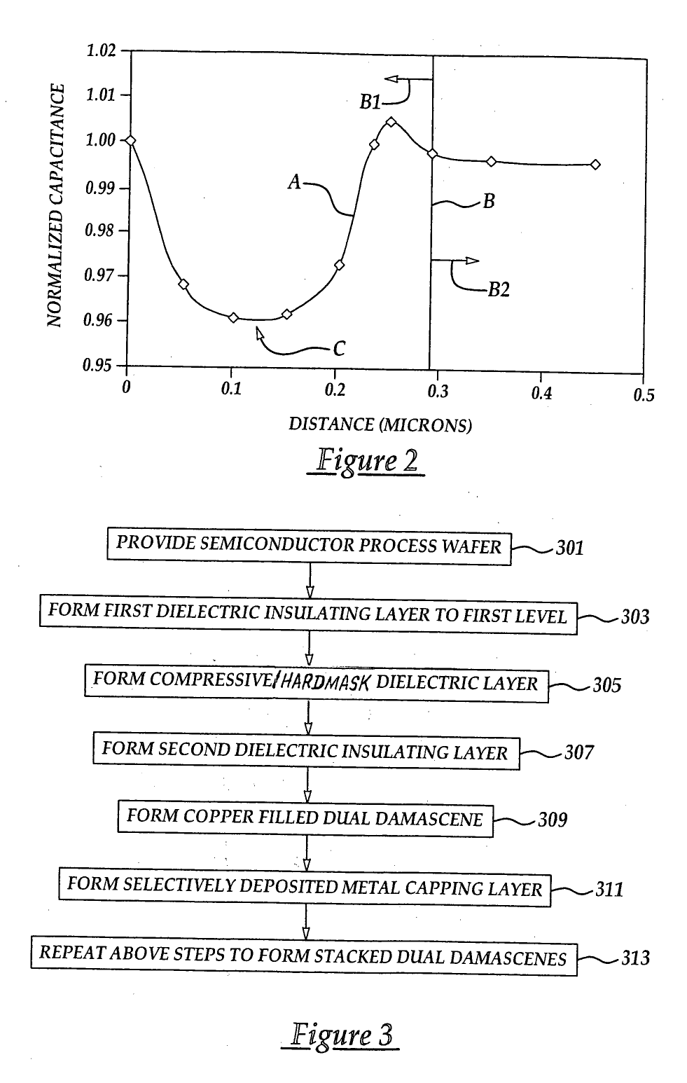

Referring to FIG. 3 is shown an exemplary process flow diagram including several embodiments of the present invention.

In process 301 a semiconductor process wafer is provided. In process 303, a first dielectric insulating layer is formed to a first level according to preferred embodiments. In process 305 a compressive dielectric layer is formed according to preferred embodiments. In process 307, a second dielectric insulating layer is formed over the compressive dielectric layer. In process 309 a copper filled dual damascene is formed. In process 311, a selectively deposited metal capping layer is deposited over the copper dual damascene. In process 313, the above processes are repeated to form stacked metallization layers including dual damascenes.

Thus, a dual damascene and metallization layer structure and method for forming the same has been presented for reducing the cumulative effect of stress buildup thereby reducing the incidence of cracking in multi-level integrated circuit devices to improve both yield and reliability, while minimizing an increase in metallization layer capacitance. By forming selectively deposited metal capping layers and forming the compressive dielectric layers at a level of minimum capacitance in a modeled metallization layer without compressive dielectric layers, the addition of the compressive dielectric layers at the determined level minimizes increases to the capacitance of the metallization layer.

The preferred embodiments, aspects, and features of the invention having been described, it will be apparent to those skilled in the art that numerous variations, modifications, and substitutions may be made without departing from the spirit of the invention as disclosed and further claimed below.

What is claimed is:

1. A semiconductor device comprising:
a substrate;
a dielectric insulating layer formed overlying the substrate;
a metal filled dual damascene structure formed in the dielectric insulating layer, wherein the metal filled dual damascene structure comprises a via portion and a trench portion; and
at least one intervening dielectric layer in compressive stress formed in the dielectric insulating layer and disposed at a level adjacent to at least one of the via portion and the trench portion of the metal filled dual damascene structure.

2. The semiconductor device of claim 1, wherein the substrate comprises at least one metallization layer, and the at least one intervening dielectric layer is disposed at about a level of minimum capacitance with, respect to the at least one metallization layer.

3. The semiconductor device of claim 1, wherein the at least one intervening dielectric layer is disposed at a level about midway with respect to a height of the via portion.

4. The semiconductor device of claim 1, wherein the at least one intervening dielectric layer is disposed adjacent the trench portion above the bottom level of the trench portion.

5. The semiconductor device of claim 1, wherein the at least one intervening dielectric layer is disposed adjacent the top of the metal filled damascene structure.

6. The semiconductor device of claim 1, wherein the at least one intervening dielectric layer has a thickness of 50 Angstroms to 700 Angstroms.

7. The semiconductor device of claim 1, wherein the at least one intervening dielectric layer is selected from the group consisting of silicon nitride, silicon oxynitride, silicon carbide, silicon oxycarbide, and silicon nitride carbide.

8. The semiconductor device of claim 1, wherein the dielectric insulating layer is selected from the group consisting of a low-K (low dielectric constant) material having a dielectric constant of less than about 3.0, and a silicon oxide based low-K material having a porous structure.

9. The semiconductor device of claim 1, wherein the metal filled dual damascene structure is a dual damascene structure filled with copper or copper alloy.

10. The semiconductor device of claim 1, further comprising a capping layer formed overlying the top of the metal filled dual damascene structure.

11. The semiconductor device of claim 10, wherein the capping layer is selected from the group consisting of Ni, W, CoWP, and COWB.

12. A semiconductor device comprising:
a substrate;
a first dielectric insulating layer formed overlying the substrate;
a first metal filled dual damascene structure formed in the first dielectric insulating layer, wherein the first metal filled dual damascene structure comprises a via portion and a trench portion; at least one first intervening dielectric layer in compressive stress formed in the first dielectric insulating layer and disposed at a level adjacent to at least one of the via portion and the trench portion of the first metal filled dual damascene;
a second dielectric insulating layer formed overlying the first dielectric insulating layer and the first metal filled dual damascene structure;
a second metal filled dual damascene structure formed in the second dielectric layer and overlying the first metal filled dual damascene structure, wherein the second metal filled dual damascene structure comprises a via portion and a trench portion; and
at least one second intervening dielectric layer in compressive stress formed in the second dielectric insulating layer and disposed at a level adjacent to at least one of the via portion and the trench portion of the second metal filled dual damascene structure.

13. The semiconductor device of claim 12, wherein the at least one first intervening dielectric layer is disposed at a level about midway with respect to a height of the via portion of the first metal filled dual damascene structure.

14. The semiconductor device of claim 12, wherein the at least one second intervening dielectric layer is disposed at a level about midway with respect to a height of the via portion of the second metal filled dual damascene structure.

15. The semiconductor device of claim 12, wherein the at least one first intervening dielectric layer is disposed adjacent the trench portion above the bottom level of the trench portion of the first metal filled dual damascene structure.

16. The semiconductor device of claim 12, wherein the at least one second intervening dielectric layer is disposed adjacent the trench portion above the bottom level of the trench portion of the second metal filled dual damascene structure.

17. The semiconductor device of claim 12, wherein the at least one first intervening dielectric layer is disposed adjacent the transition between first metal filled dual damascene structure and the second metal filled dual damascene structure.

18. The semiconductor device of claim 12, wherein the at least one second intervening dielectric layer is disposed adjacent the top of the second metal filled dual damascene structure.

19. The semiconductor device of claim 12, wherein the at least one first intervening dielectric layer and the at least one second intervening dielectric layer are selected from the group consisting of silicon nitride, silicon oxynitride, silicon carbide, silicon oxycarbide, and silicon nitride carbide.

20. The semiconductor device of claim 12, wherein the first dielectric insulating layer and the second dielectric insulating layer are selected from the group consisting of a low-K (low dielectric constant) material having a dielectric constant of less than about 3.0, and a silicon oxide based low-K material having a porous structure.

21. The semiconductor device of claim 12, wherein the first metal filled dual damascene and the second metal filled dual damascene are dual damascene structures filled with copper or copper alloy.

22. The semiconductor device of claim 12, further comprising:
a first capping layer formed overlying the top of the first metal filled dual damascene; and
a second capping layer formed overlying the top of the second metal filled dual damascene.

23. The semiconductor device of claim 22, wherein the first capping layer and the second capping layer are selected from the group consisting of Ni, W, CoWP, and CoWB.
